(19) United States
(12) Patent Application Publication
(10) Pub. No.: US 2025/0233077 A1
(43) Pub. Date: Jul. 17, 2025

(54) POWER SEMICONDUCTOR DEVICE

(71) Applicant: Mitsubishi Electric Corporation, Tokyo (JP)

(72) Inventors: Maki HASEGAWA, Tokyo (JP); Toshiya TADAKUMA, Tokyo (JP)

(73) Assignee: Mitsubishi Electric Corporation, Tokyo (JP)

(21) Appl. No.: 18/948,392

(22) Filed: Nov. 14, 2024

(30) Foreign Application Priority Data
Jan. 17, 2024 (JP) 2024-004953

(51) Int. Cl. H01L 23/538; H01L 25/065

(52) U.S. Cl. CPC H01L 23/5386; H01L 25/0655

(57) ABSTRACT

A power semiconductor device including: a plurality of semiconductor modules; and a first bus bar and a second bus bar electrically connected to a first main electrode terminal and a second main electrode terminal, respectively, of each of the semiconductor modules, wherein the semiconductor modules are arrayed without any overlap in a first direction that is a thickness direction, and the first and second main electrode terminals protrude from one side surface of the semiconductor modules, and are disposed side by side with a space in a second direction that is an alignment direction of the semiconductor modules, the power semiconductor device including an insulating medium inserted between the first and second main electrode terminals.

### BACKGROUND OF THE INVENTION

### Field of the Invention

The present disclosure relates to a power semiconductor device, and particularly to a power semiconductor device that ensures a current capacity of semiconductor modules and reduces heat generated in a terminal portion.

### Description of the Background Art

Generally, large currents flow through power semiconductor modules typified by an insulated gate bipolar transistor (IGBT), an intelligent power module (IPM), and a transfer-molded power module (TPM). Such a power semiconductor module includes a main electrode terminal through which a large current flows and to which a high voltage is applied, and a control terminal that controls ON and OFF of switching devices. The control terminal is connected to an external connector, and controls switching of the power semiconductor module using an external control signal.

P terminals and N terminals of adjacent main electrode terminals are connected to respective laminated bus bars. The bus bars are further connected to a capacitor bank. The bottom of the modules is disposed in contact with a heat sink such as fins.

Since a large current flows through the main electrode terminals, a temperature rise is a problem. Furthermore, since a high voltage is applied to the main electrode terminals, a spatial insulation distance needs to be kept between the terminals for safety. Thus, it is difficult to increase a terminal width.

Japanese Patent Application Laid-Open No. 2018-67990 discloses a technology for downsizing a power converter while maintaining an electrical insulation between main electrode terminals, by disposing insulating components between the main electrode terminals connected to bus bars and disposing the main electrode terminals to overlap one another to narrow the space between the main electrode terminals.

In the power converter disclosed in Japanese Patent Application Laid-Open No. 2018-67990, an alignment direction of the main electrode terminals is identical to an alignment direction of semiconductor modules. Thus, there is a constraint in disposing the insulating components between the main electrode terminals, and it has been difficult to increase a terminal width.

### SUMMARY

The object of the present disclosure is to provide a power semiconductor device that ensures a current capacity by increasing a terminal width of a main electrode terminal of a semiconductor module and reduces heat generated in a terminal portion.

The power semiconductor device according to the present disclosure includes: a plurality of semiconductor modules; and a first bus bar and a second bus bar electrically connected to a first main electrode terminal and a second main electrode terminal, respectively, of each of the semiconductor modules, wherein the semiconductor modules are arrayed without any overlap in a first direction that is a thickness direction, and the first and second main electrode terminals protrude from one side surface of the semiconductor modules, and are disposed side by side with a space in a second direction that is an alignment direction of the semiconductor modules, the power semiconductor device including an insulating medium inserted between the first and second main electrode terminals.

In the power semiconductor device according to the present disclosure, inserting the insulating medium between the first and second main electrode terminals can shorten the spatial insulation distance, and increase an electrode width that is a length of each of the first and second main electrode terminals in the second direction.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a plan view illustrating a structure of a power semiconductor device according to Embodiment 1 of the present disclosure;

FIG. 2 is a perspective view illustrating a structure of a connection portion between main electrode terminals of a semiconductor module and bus bars;

FIG. 3 is a perspective view illustrating a structure of a connection portion between the main electrode terminals of the semiconductor module and the bus bars;

FIG. 4 is a plan view of the semiconductor module;

FIG. 5 is a side view of the semiconductor module in a power semiconductor device according to Embodiment 2 of the present disclosure;

FIG. 6 is a plan view illustrating a structure of the power semiconductor device according to Embodiment 2 of the present disclosure;

FIG. 7 is a side view of the semiconductor module in a power semiconductor device according to a modification of Embodiment 2 of the present disclosure;

FIG. 8 is a plan view illustrating a structure of the power semiconductor device according to the modification of Embodiment 2 of the present disclosure;

FIG. 9 is a plan view illustrating a structure of the semiconductor module in a power semiconductor device according to Embodiment 3 of the present disclosure;

FIG. 10 is a side view of the semiconductor module in the power semiconductor device according to Embodiment 3 of the present disclosure;

FIG. 11 is a side view of the semiconductor module in the power semiconductor device according to Embodiment 3 of the present disclosure;

FIG. 12 is a side view of the semiconductor module in the power semiconductor device according to Embodiment 4 of the present disclosure;

FIG. 13 is a side view of the semiconductor module in a power semiconductor device according to a modification of Embodiment 4 of the present disclosure; and

FIG. 14 is a side view of the semiconductor module in the power semiconductor device according to Embodiment 4 of the present disclosure.

### DESCRIPTION OF THE PREFERRED EMBODIMENTS

### Embodiment 1

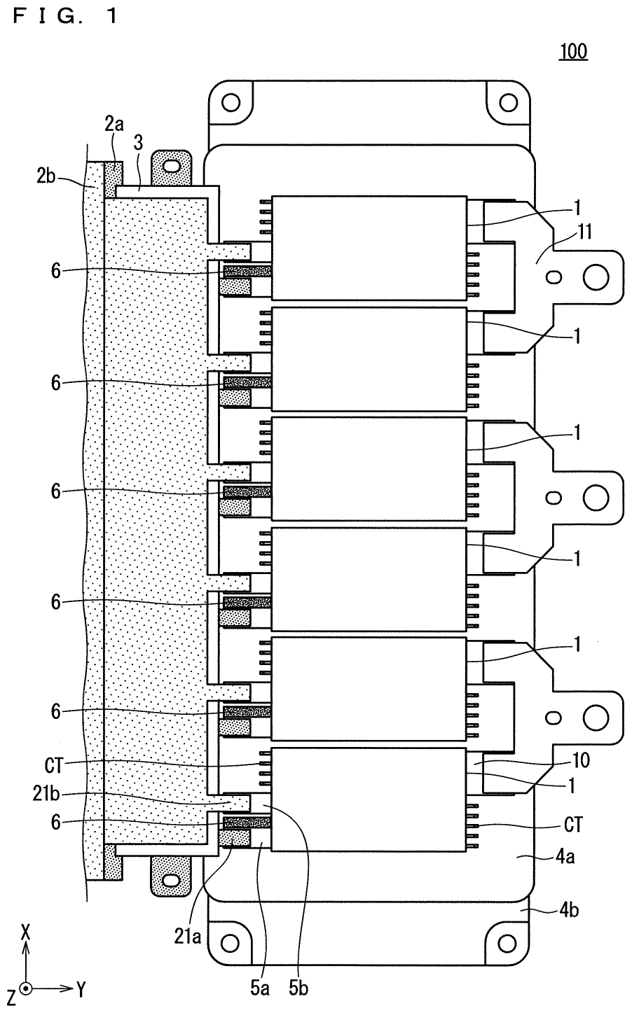

FIG. 1 is a plan view illustrating a structure of a power semiconductor device 100 according to Embodiment 1 of the present disclosure.

As illustrated in FIG. 1, the power semiconductor device 100 includes six semiconductor modules 1 mounted on an upper surface of a cooling component 4a on a cooling mechanism 4b such as a cooling water system, and a bus bar 2a (a first bus bar) and a bus bar 2b (a second bus bar) that are connected to a main electrode terminal 5a (a first main electrode terminal) and a main electrode terminal 5b (a second main electrode terminal), respectively, that are spaced apart from each other and protrude from the side surface of each of the semiconductor modules 1.

The bus bars 2a and 2b extend in the X direction that is an alignment direction of the six semiconductor modules 1, and are connected to a capacitor bank that is an assembly of a plurality of capacitors, in an end portion that is not illustrated in the Y direction orthogonal to the X direction. This capacitor bank is used as, for example, a filter capacitor of a power conversion circuit.

Each of the semiconductor modules 1 includes an output terminal 10 protruding from the side surface opposite to the side from which the main electrode terminals 5a and 5b protrude. The output terminals 10 of the adjacent semiconductor modules 1 are connected in common to a terminal assembly 11. The terminal assemblies 11 are electrically connected to an outside of the power semiconductor device 100 through an external terminal assembly that is not illustrated.

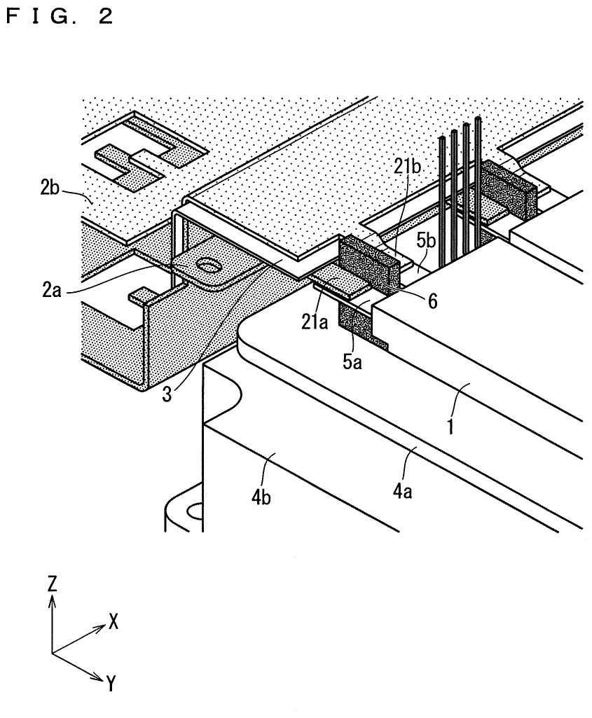

FIG. 2 is a perspective view illustrating a structure of a connection portion between the main electrode terminals 5a and 5b of the semiconductor module 1 and the bus bars 2a and 2b. The bus bars 2a and 2b are laminated in the Z direction that is an up and down direction, and are electrically insulated by an insulation sheet 3 which is referred to as a laminator and has an electrical resistance of approximately 100 MΩ to keep the spatial insulation distance. In Embodiment 1, the bus bar 2a is a p-potential bus bar on a high potential side, and the bus bar 2b is an n-potential bus bar on a low potential side.

For example, a composite of a polyethylene terephthalate (PET) film and aramid paper can be used as the insulation sheet 3. The insulation sheet 3 can cover not only a portion between the bus bars 2a and 2b, but also the upper surfaces and the lower surfaces of the bus bars 2a and 2b.

As illustrated in FIG. 2, the bus bar 2a has a structure which includes a plurality of bus bar terminals 21a (first bus bar terminals) extending from an edge on the semiconductor module 1 side, and in which the upper surface of the main electrode terminal 5a of the semiconductor module 1 is connected to each of the bus bar terminals 21a.

The bus bar 2b has a structure which includes a plurality of bus bar terminals 21b (second bus bar terminals) extending from the edge on the semiconductor module 1 side, and in which the upper surface of the main electrode terminal 5b of the semiconductor module 1 is connected to each of the bus bar terminals 21b.

An insulating medium 6 that is a sheet-like insulating material is inserted between the main electrode terminal 5a and the main electrode terminal 5b that protrude from the side surface of the semiconductor module 1. The main electrode terminal 5a and the main electrode terminal 5b are connected to the bus bar 2a and the bus bar 2b, respectively. Thus, the main electrode terminal 5a has a p-potential, and the main electrode terminal 5b has a n-potential. Although the main electrode terminals 5a and 5b originally need to be disposed at a separation distance necessary to keep the spatial insulation distance, inserting the insulating medium 6 between the main electrode terminal 5a and the main electrode terminal 5b in the power semiconductor device 100 according to Embodiment 1 can shorten the spatial insulation distance, and increase an electrode width that is a length of each of the main electrode terminal 5a and the main electrode terminal 5b in the X direction.

The insulating medium 6 can be made of a paper material such as aramid paper and resin paper, or a resin such as a nylon film, a polyester film, a polyphenylene sulfide (PPS) film, and can have a thickness of approximately 100 μm at its thinnest. Using the sheet-like insulating medium 6 can suppress an increase in the manufacturing cost.

The insulating medium 6 can be thick to the extent that the breakdown voltage can be secured. As the insulating medium 6 is thicker, the breakdown voltage increases. Thus, the insulating medium 6 can be as thick as the space between the adjacent main electrode terminals 5a and 5b at maximum. Furthermore, the length of the insulating medium 6 in the Y direction can be as great as that of each of the main electrode terminals 5a and 5b in the Y direction.

Here, the semiconductor modules 1 are arrayed without any overlap in the Z direction that is a thickness direction in the power semiconductor device 100. The main electrode terminals 5a and 5b are disposed side by side in the X direction that is an alignment direction of the semiconductor modules 1. The terminal surfaces of the main electrode terminals 5a and 5b do not overlap each other. Since the insulating medium 6 is disposed between the main electrode terminals 5a and 5b in the X direction that is an alignment direction of the main electrode terminals 5a and 5b, thinning the insulating medium 6 as much as possible while the insulating medium 6 can maintain the breakdown voltage can significantly increase the terminal width that is the length of each of the main electrode terminals 5a and 5b in the X direction.

This allows the larger current to flow, and can increase the amount of heat dissipation in a terminal portion and reduce the heat, without increasing the dimensions of the semiconductor modules 1.

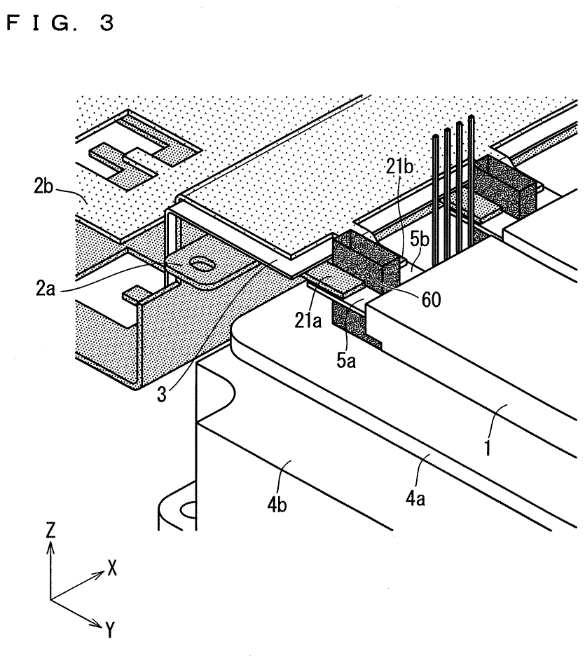

Instead of thickening the insulating medium 6, an insulating medium 60 that is hollow and tubular can be used. FIG. 3 is a perspective view illustrating a structure of a connection portion between the main electrode terminals 5a and 5b of the semiconductor module 1 and the bus bars 2a and 2b when the hollow and tubular insulating medium 60 is used. Making the width of the insulating medium 60 in the X direction as large as the space between the adjacent main electrode terminals 5a and 5b and making the length of the insulating medium 60 in the Y direction as great as the length of each of the main electrode terminals 5a and 5b in the Y direction can completely fill the space between the main electrode terminals 5a and 5b. Use of the hollow and tubular insulating medium 60 can reduce its weight.

Fastening the insulating mediums 6 and 60 by bonding the insulating mediums 6 and 60 to at least one of the main electrode terminal 5a or 5b through an adhesive can inhibit the insulating mediums 6 and 60 from moving by, for example, vibrations.

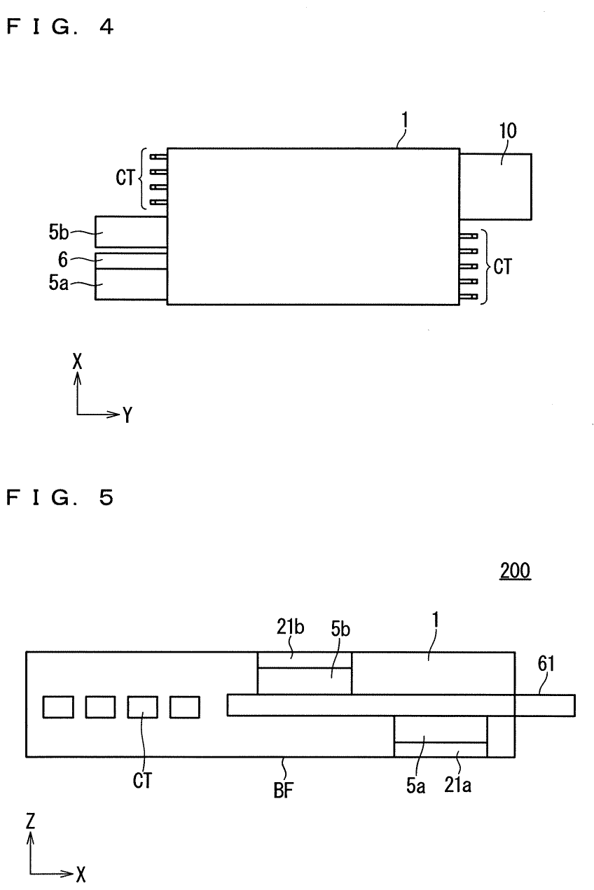

FIG. 4 is a plan view of the semiconductor module 1 when viewed from the top. As illustrated in FIG. 4, each of the semiconductor modules 1 includes a plurality of control terminals CT protruding from the side surface from which the main electrode terminals 5a and 5b protrude, and from the side surface from which the output terminal 10 protrudes. Each of the control terminals CT receives a control signal that controls ON and OFF of switching devices included in the semiconductor module 1, is bent in the Z direction orthogonal to the protruding direction (Y direction), and is connected to an external connector that is not illustrated.

### Embodiment 2

FIG. 5 is a side view of the semiconductor module 1 in a power semiconductor device 200 according to Embodiment 2 of the present disclosure when viewed from the side surface from which the main electrode terminals 5a and 5b protrude.

As illustrated in FIG. 5, the main electrode terminals 5a and 5b are disposed at different positions such that the main electrode terminals 5a and 5b in the Z direction that is a thickness direction of the semiconductor module 1 have a step, and an insulating medium 61 extending in the X direction that is an alignment direction of the main electrode terminals 5a and 5b is inserted between the main electrode terminals 5a and 5b across the step. Inserting the insulating medium 61 allows the bus bar terminal 21b to be connected to the upper surface of the main electrode terminal 5b and allows the bus bar terminal 21a to be connected to the lower surface of the main electrode terminal 5a.

Although FIG. 5 illustrates a structure in which the main electrode terminal 5a at a higher potential is disposed closer to a bottom BF of the semiconductor module 1 and the main electrode terminal 5b at a lower potential is disposed opposite to the main electrode terminal 5a, the main electrode terminals 5a and 5b can be inverted in the up and down direction.

Inserting the insulating medium 61 between the main electrode terminals 5a and 5b that are disposed at different positions with the step can keep the spatial insulation distance between the main electrode terminals 5a and 5b. Thus, the terminal width that is the length of each of the main electrode terminals 5a and 5b in the X direction can be significantly increased. For example, the terminal width can be increased to the extent that the terminal surfaces of the main electrode terminals 5a and 5b overlap each other when viewed from the Z direction.

Consequently, the larger current can flow, and the amount of heat dissipation in a terminal portion can be increased and the heat can be reduced, without increasing the dimensions of the semiconductor modules 1. Furthermore, since the insulating medium 61 is sandwiched between the main electrode terminals 5a and 5b, this facilitates, for example, its positioning.

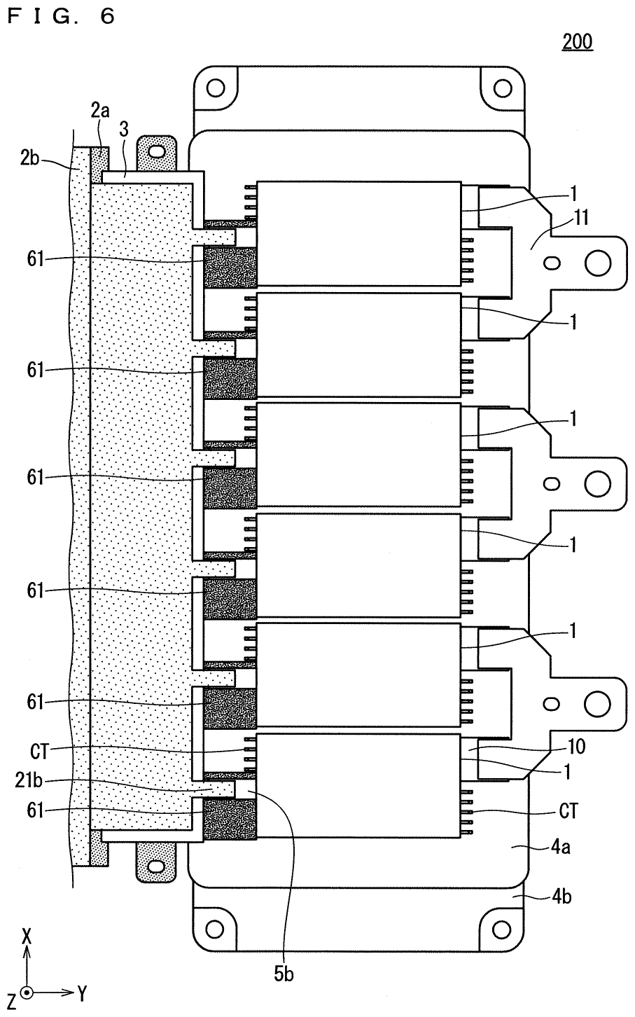

FIG. 6 is a plan view illustrating a structure of the power semiconductor device 200 according to Embodiment 2 of the present disclosure. In FIG. 6, the same reference numerals are used for the same structures as those of the power semiconductor device 100 described with reference to FIG. 1, and the overlapping description will be omitted.

As illustrated in FIG. 6, the insulating medium 61 extending in the X direction that is an alignment direction of the main electrode terminals 5a and 5b is inserted between the main electrode terminals 5a and 5b of each of the semiconductor modules 1 in the power semiconductor device 200. Since the insulating mediums 61 cover the main electrode terminals 5a, the main electrode terminals 5a cannot be visually identified.

Although the insulating mediums 61 can be made of the same material as that of the insulating medium 6 described in Embodiment 1, extensions of the insulation sheet 3 inserted between the bus bars 2a and 2b can be the insulating mediums 61. Forming the insulating mediums 61 by extending the insulation sheet 3 can save a process of inserting the insulating mediums 61, and eliminate the manufacturing step.

### Modifications

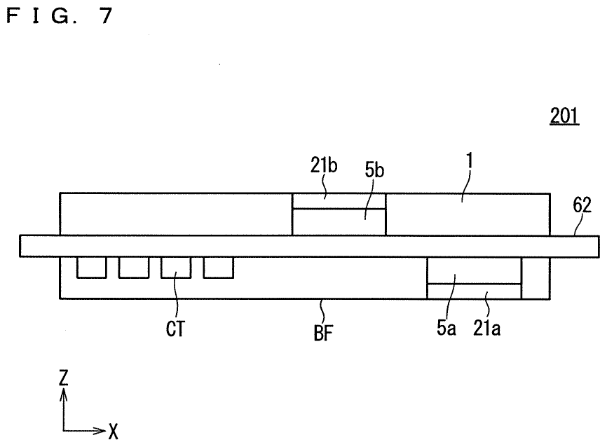

FIG. 7 is a side view of the semiconductor module 1 in a power semiconductor device 201 that is a modification of Embodiment 2 of the present disclosure when viewed from the side surface from which the main electrode terminals 5a and 5b protrude.

As illustrated in FIG. 7, the main electrode terminals 5a and 5b are disposed at different positions such that the main electrode terminals 5a and 5b in the Z direction that is a thickness direction of the semiconductor module 1 have a step, and the control terminals CT are disposed closer to the bottom BF of the semiconductor module 1 in the Z direction to form the same plane with the main electrode terminal 5a. Then, an insulating medium 62 extending in the X direction is inserted between the control terminals CT and the main electrode terminals 5a and 5b disposed at the different positions in the Z direction. The insulating medium 62 is disposed to cover the main electrode terminals 5a and the control terminals CT. Inserting the insulating medium 62 allows the bus bar terminal 21b to be connected to the upper surface of the main electrode terminal 5b and allows the bus bar terminal 21a to be connected to the lower surface of the main electrode terminal 5a.

Inserting the insulating medium 62 between the main electrode terminals 5a and 5b that are disposed at the different positions in the Z direction can keep the spatial insulation distance between the main electrode terminals 5a and 5b. Thus, the power semiconductor device 201 is identical to the power semiconductor device 200 according to Embodiment 2 in that the terminal width that is the length of each of the main electrode terminals 5a and 5b in the X direction can be significantly increased.

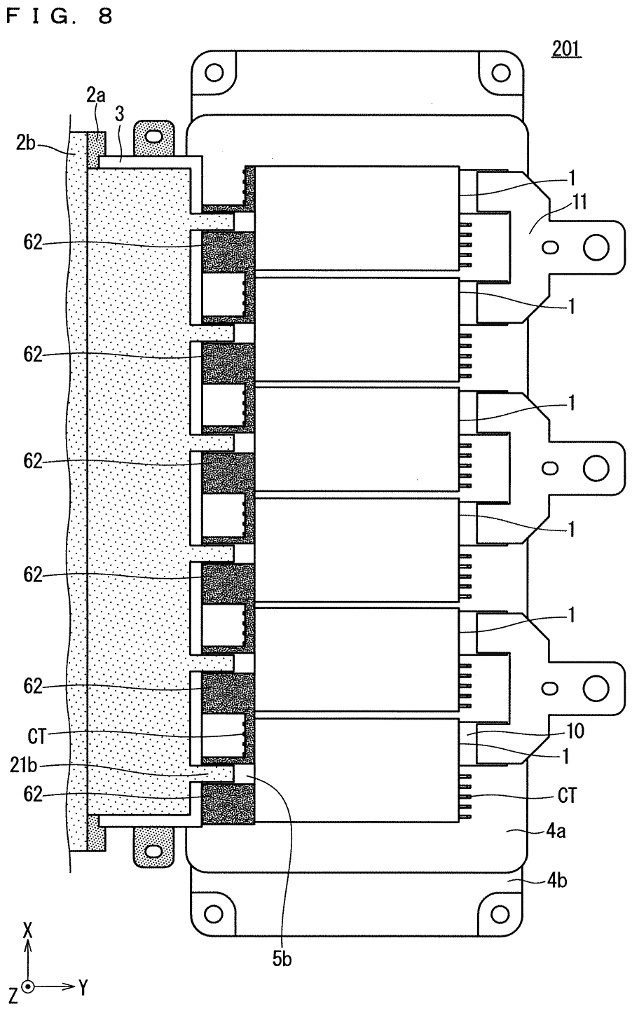

FIG. 8 is a plan view illustrating a structure of the power semiconductor device 201 according to a modification of Embodiment 2 of the present disclosure. In FIG. 8, the same reference numerals are used for the same structures as those of the power semiconductor device 100 described with reference to FIG. 1, and the overlapping description will be omitted.

As illustrated in FIG. 8, the insulating medium 62 extending in the X direction is inserted in the power semiconductor device 201 between the control terminals CT and the main electrode terminals 5a and 5b of each of the semiconductor modules 1. Since the insulating mediums 62 cover the main electrode terminals 5a, the main electrode terminals 5a cannot be visually identified.

As illustrated in FIG. 8, since the insulating mediums 62 can be integrally disposed across the entire terminal portion of the array of the semiconductor modules 1, the assembly workability will be improved more than the power semiconductor device 200 according to Embodiment 2 in which the insulating medium 61 is disposed for each of the semiconductor modules 1.

In the semiconductor module 1 in FIG. 7, the main electrode terminal 5b at a lower potential is disposed closer to the control terminals CT and the main electrode terminal 5a at a higher potential is disposed distant from the control terminals CT on distances in the X direction. When the main electrode terminal 5a is disposed closer to the control terminals CT, covering the control terminals CT with the insulating medium 62 can produce advantages of keeping the spatial insulation distance between the main electrode terminal 5a and the control terminals CT, and preventing a breakdown between the main electrode terminal 5a and the control terminals CT.

Although the insulating mediums 62 can be made of the same material as that of the insulating medium 6 described in Embodiment 1, extensions of the insulation sheet 3 inserted between the bus bars 2a and 2b can be the insulating mediums 62. Forming the insulating mediums 62 by extending the insulation sheet 3 can save a process of inserting the insulating mediums 62, and eliminate the manufacturing step.

### Embodiment 3

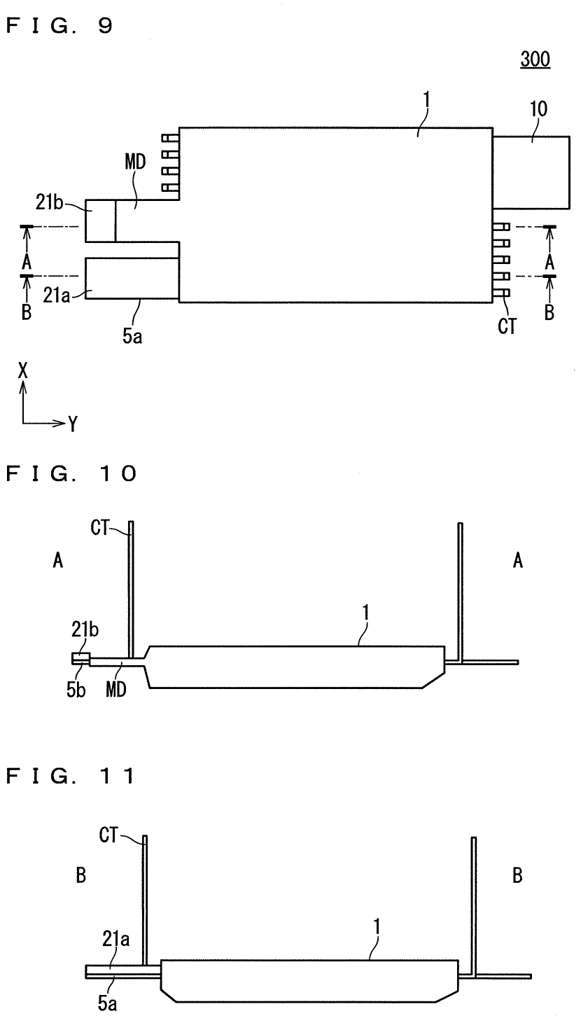

FIG. 9 is a plan view illustrating a structure of the semiconductor module 1 in a power semiconductor device 300 according to Embodiment 3 of the present disclosure when viewed from the top.

Each of FIGS. 10 and 11 is a side view of the semiconductor module 1 in FIG. 9 when viewed from a side surface of a long side orthogonal to side surfaces of short sides from which the main electrode terminals 5a and 5b and the output terminal 10 protrude. FIG. 10 is a side view corresponding to a cross-sectional view taken along a line A-A in FIG. 9, and FIG. 11 is a side view corresponding to a cross-sectional view taken along a line B-B in FIG. 9. The illustration of an internal structure of the semiconductor module 1 is omitted for convenience.

As illustrated in FIGS. 9 to 11, a transfer molding resin MD sealing the semiconductor module 1 covers the main electrode terminal 5b except its tip, and the bus bar terminal 21b is connected to the tip. The main electrode terminal 5a is not covered with the transfer molding resin MD, and the bus bar terminal 21a is connected to an entire portion protruding from the side surface of the semiconductor module 1. The main electrode terminal 5a can be covered with the transfer molding resin MD.

As such, covering at least one of the main electrode terminal 5a or 5b with a resin can further shorten the spatial insulation distance between the main electrode terminals 5a and 5b, and can increase the terminal width that is the length of each of the main electrode terminals 5a and 5b in the X direction. Furthermore, extending the bus bar terminal 21a closer to the semiconductor module 1 and connecting the bus bar terminal 21a to the main electrode terminal 5a can thicken the terminal portion, further increase a current capacity, and further suppress a temperature rise.

### Embodiment 4

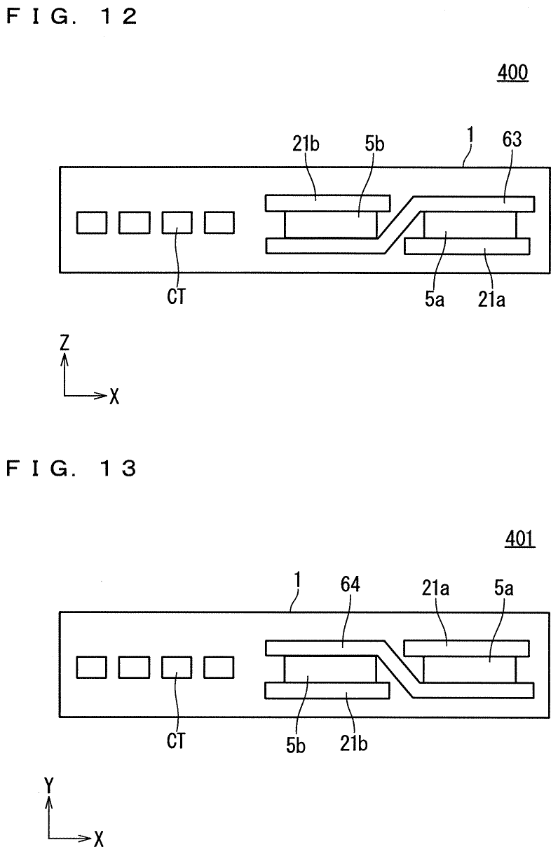

FIG. 12 is a side view of the semiconductor module 1 in a power semiconductor device 400 according to Embodiment 4 of the present disclosure when viewed from the side surface from which the main electrode terminals 5a and 5b protrude.

As illustrated in FIG. 12, terminal positions of the main electrode terminals 5a and 5b in the Z direction that is a thickness direction of the semiconductor module 1 are identical in the semiconductor module 1. An insulating medium 63, which includes a bend with a step in the Z direction that is an up and down direction and which extends in the X direction, is inserted between the main electrode terminals 5a and 5b in the semiconductor module 1.

The insulating medium 63 has a step such that the insulating medium 63 covers the upper surface of the main electrode terminal 5a and the lower surface of the main electrode terminal 5b. Inserting the insulating medium 63 allows the bus bar terminal 21b to be connected to the upper surface of the main electrode terminal 5b and allows the bus bar terminal 21a to be connected to the lower surface of the main electrode terminal 5a.

Inserting, between the main electrode terminals 5a and 5b, the insulating medium 63 with the step in the Z direction can keep the spatial insulation distance between the main electrode terminals 5a and 5b. Thus, the terminal width that is the length of each of the main electrode terminals 5a and 5b in the X direction can be increased.

Consequently, the larger current can flow, and the amount of heat dissipation in the terminal portion can be increased and the heat can be reduced, without increasing the dimensions of the semiconductor modules 1.

Although the insulating medium 63 can be made of the same material as that of the insulating medium 6 described in Embodiment 1, an extension of the insulation sheet 3 inserted between the bus bars 2a and 2b can be the insulating medium 63. Forming the insulating medium 63 by extending the insulation sheet 3 can save a process of inserting the insulating medium 63, and eliminate the manufacturing step.

### Modifications

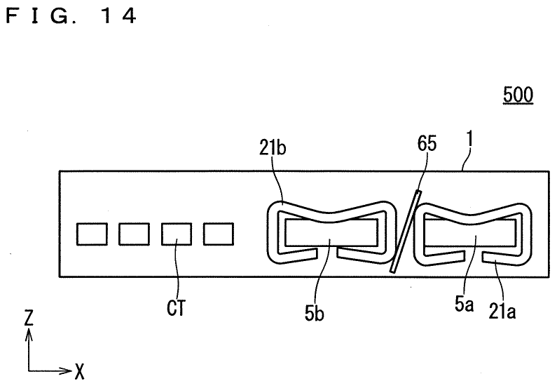

FIG. 13 is a side view of the semiconductor module 1 in a power semiconductor device 401 that is a modification of Embodiment 4 of the present disclosure when viewed from the side surface from which the main electrode terminals 5a and 5b protrude.

As illustrated in FIG. 13, terminal positions of the main electrode terminals 5a and 5b in the Z direction that is a thickness direction of the semiconductor module 1 are identical in the semiconductor module 1. An insulating medium 64, which includes a bend with a step in the Z direction that is an up and down direction and which extends in the X direction, is inserted between the main electrode terminals 5a and 5b in the semiconductor module 1.

The insulating medium 64 has a step such that the insulating medium 64 covers the lower surface of the main electrode terminal 5a and the upper surface of the main electrode terminal 5b. Inserting the insulating medium 64 allows the bus bar terminal 21b to be connected to the lower surface of the main electrode terminal 5b and allows the bus bar terminal 21a to be connected to the upper surface of the main electrode terminal 5a.

Inserting, between the main electrode terminals 5a and 5b, the insulating medium 64 with the step in the Z direction can keep the spatial insulation distance between the main electrode terminals 5a and 5b. Thus, the terminal width that is the length of each of the main electrode terminals 5a and 5b in the X direction can be increased.

Consequently, the larger current can flow, and the amount of heat dissipation in the terminal portion can be increased and the heat can be reduced, without increasing the dimensions of the semiconductor modules 1.

Although the insulating medium 64 can be made of the same material as that of the insulating medium 6 described in Embodiment 1, an extension of the insulation sheet 3 inserted between the bus bars 2a and 2b can be the insulating medium 64. Forming the insulating medium 64 by extending the insulation sheet 3 can save a process of inserting the insulating medium 64, and eliminate the manufacturing step.

### Embodiment 5

FIG. 14 is a side view of the semiconductor module 1 in a power semiconductor device 500 according to Embodiment 5 of the present disclosure when viewed from the side surface from which the main electrode terminals 5a and 5b protrude.

As illustrated in FIG. 14, terminal positions of the main electrode terminals 5a and 5b in the Z direction that is a thickness direction of the semiconductor module 1 are identical in the semiconductor module 1. The bus bar terminal 21a and the bus bar terminal 21b are connected to the main electrode terminal 5a and the main electrode terminal 5b to surround the main electrode terminal 5a and the main electrode terminal 5b, respectively. An insulating medium 65 is disposed between the adjacent bus bar terminals 21a and 21b to keep the spatial insulation distance between the bus bar terminals 21a and 21b.

Surrounding the main electrode terminal 5a and the main electrode terminal 5b by the bus bar terminal 21a and the bus bar terminal 21b, respectively, can increase a contact area between the main electrode terminals 5a and 5b and the bus bar terminals 21a and 21b, thicken the terminal portion, and further suppress a temperature rise.

Although a distance between the bus bar terminals 21a and 21b is shortened, the insulating medium 65 facilitates maintaining the spatial insulation distance.

The bus bar terminal 21a and the bus bar terminal 21b are tubularly formed in advance to surround the main electrode terminal 5a and the main electrode terminal 5b, respectively. During assembly, inserting the bus bar terminal 21a and the bus bar terminal 21b around the main electrode terminal 5a and the main electrode terminal 5b, and applying external pressure from outside of the bus bar terminals 21a and 21b by crimping can connect the bus bar terminal 21a and the bus bar terminal 21b to the main electrode terminal 5a and the main electrode terminal 5b, respectively.

Embodiments of the present disclosure can be freely combined, and appropriately modified or omitted within the scope of the disclosure.

A summary of various aspects of the present disclosure will be hereinafter described as Appendixes.

### Appendix 1

A power semiconductor device, comprising:
a plurality of semiconductor modules; and
a first bus bar and a second bus bar electrically connected to a first main electrode terminal and a second main electrode terminal, respectively, of each of the semiconductor modules,
wherein the semiconductor modules are arrayed without any overlap in a first direction that is a thickness direction, and
the first and second main electrode terminals protrude from one side surface of the semiconductor modules, and are disposed side by side with a space in a second direction that is an alignment direction of the semiconductor modules, the power semiconductor device comprising an insulating medium inserted between the first and second main electrode terminals.

### Appendix 2

The power semiconductor device according to appendix 1,
wherein the insulating medium is inserted between the first and second main electrode terminals in the second direction of the first and second main electrode terminals.

### Appendix 3

The power semiconductor device according to appendix 2,
wherein the insulating medium is a sheet-like insulating material.

### Appendix 4

The power semiconductor device according to appendix 2,
wherein the insulating medium is an insulating material that is hollow and tubular.

### Appendix 5

The power semiconductor device according to appendix 1,
wherein the first and second main electrode terminals are disposed at different positions on the one side surface such that the first and second main electrode terminals have a step in the first direction of the semiconductor modules, and
the insulating medium is inserted between the first and second main electrode terminals across the step to extend in the second direction.

### Appendix 6

The power semiconductor device according to appendix 5,
wherein each of the semiconductor modules includes a plurality of control terminals protruding from the one side surface,
the control terminals are disposed at positions different from positions of the first and second main electrode terminals in the second direction, and are disposed in the first direction at positions identical to a position of any one of the first and second main electrode terminals, and
the insulating medium extends in the second direction to cover the control terminals.

### Appendix 7

The power semiconductor device according to appendix 1,
wherein the first and second main electrode terminals are disposed on the one side surface at positions identical in the first direction of the semiconductor modules, and
the insulating medium includes a bend with a step in the first direction between the first and second main electrode terminals, and is inserted in each of the semiconductor modules to extend in the second direction.

### Appendix 8

The power semiconductor device according to appendix 1,
wherein the first bus bar includes a first bus bar terminal connected to the first main electrode terminal,
the second bus bar includes a second bus bar terminal connected to the second main electrode terminal,
the first bus bar terminal is connected to the first main electrode terminal to surround the first main electrode terminal,
the second bus bar terminal is connected to the second main electrode terminal to surround the second main electrode terminal, and
the insulating medium is inserted between the first main electrode terminal and the second main electrode terminal surrounded by the first bus bar terminals and the second bus bar terminal, respectively, in the second direction of the first and second main electrode terminals.

### Appendix 9

The power semiconductor device according to any one of appendixes 5 to 8,
wherein the first and second bus bars are disposed to face each other with a space in the first direction,
an insulation sheet is disposed between the first and second bus bars, and
the insulating medium is formed by extending a part of the insulation sheet.

### Appendix 10

A power semiconductor device, comprising:
a plurality of semiconductor modules; and
a first bus bar and a second bus bar electrically connected to a first main electrode terminal and a second main electrode terminal, respectively, of each of the semiconductor modules,
wherein the semiconductor modules are arrayed without any overlap in a first direction that is a thickness direction,
the first bus bar includes a first bus bar terminal connected to the first main electrode terminal,
the second bus bar includes a second bus bar terminal connected to the second main electrode terminal,
the first and second main electrode terminals are disposed side by side with a space in a second direction that is an alignment direction of the semiconductor modules,
the first main electrode terminal protrudes from one side surface of the semiconductor modules,
the second main electrode terminal is covered with a molding resin except a tip of the second main electrode terminal, the molding resin being included in the semiconductor modules,
the first bus bar terminal is formed into a length to cover a protruding portion of the first main electrode terminal and to be connected to the first main electrode terminal, and
the second bus bar terminal is formed into a length to cover the tip of the second main electrode terminal and to be connected to the second main electrode terminal.

While the invention has been shown and described in detail, the foregoing description is in all aspects illustrative and not restrictive. It is therefore understood that numerous modifications and variations can be devised without departing from the scope of the invention.

What is claimed is:

1. A power semiconductor device, comprising:
a plurality of semiconductor modules; and
a first bus bar and a second bus bar electrically connected to a first main electrode terminal and a second main electrode terminal, respectively, of each of the semiconductor modules,
wherein the semiconductor modules are arrayed without any overlap in a first direction (Z direction) that is a thickness direction, and
the first and second main electrode terminals protrude from one side surface of the semiconductor modules, and are disposed side by side with a space in a second direction that is an alignment direction of the semiconductor modules, the power semiconductor device comprising an insulating medium inserted between the first and second main electrode terminals.

2. The power semiconductor device according to claim 1,
wherein the insulating medium is inserted between the first and second main electrode terminals in the second direction of the first and second main electrode terminals.

3. The power semiconductor device according to claim 2,
wherein the insulating medium is a sheet-like insulating material.

4. The power semiconductor device according to claim 2,
wherein the insulating medium is an insulating material that is hollow and tubular.

5. The power semiconductor device according to claim 1,
wherein the first and second main electrode terminals are disposed at different positions on the one side surface such that the first and second main electrode terminals have a step in the first direction of the semiconductor modules, and
the insulating medium is inserted between the first and second main electrode terminals across the step to extend in the second direction.

6. The power semiconductor device according to claim 5,
wherein each of the semiconductor modules includes a plurality of control terminals protruding from the one side surface,
the control terminals are disposed at positions different from positions of the first and second main electrode terminals in the second direction, and are disposed in the first direction at positions identical to a position of any one of the first and second main electrode terminals, and
the insulating medium extends in the second direction to cover the control terminals.

7. The power semiconductor device according to claim 1,
wherein the first and second main electrode terminals are disposed on the one side surface at positions identical in the first direction of the semiconductor modules, and
the insulating medium includes a bend with a step in the first direction between the first and second main electrode terminals, and is inserted in each of the semiconductor modules to extend in the second direction.

8. The power semiconductor device according to claim 1,
wherein the first bus bar includes a first bus bar terminal connected to the first main electrode terminal,
the second bus bar includes a second bus bar terminal connected to the second main electrode terminal,
the first bus bar terminal is connected to the first main electrode terminal to surround the first main electrode terminal,
the second bus bar terminal is connected to the second main electrode terminal to surround the second main electrode terminal, and
the insulating medium is inserted between the first main electrode terminal and the second main electrode terminal surrounded by the first bus bar terminals and the second bus bar terminal, respectively, in the second direction of the first and second main electrode terminals.

9. The power semiconductor device according to claim 5,
wherein the first and second bus bars are disposed to face each other with a space in the first direction,
an insulation sheet is disposed between the first and second bus bars, and
the insulating medium is formed by extending a part of the insulation sheet.

10. The power semiconductor device according to claim 6,
wherein the first and second bus bars are disposed to face each other with a space in the first direction,
an insulation sheet is disposed between the first and second bus bars, and
the insulating medium is formed by extending a part of the insulation sheet.

11. The power semiconductor device according to claim 7,
wherein the first and second bus bars are disposed to face each other with a space in the first direction,
an insulation sheet is disposed between the first and second bus bars, and
the insulating medium is formed by extending a part of the insulation sheet.

12. The power semiconductor device according to claim 8,
wherein the first and second bus bars are disposed to face each other with a space in the first direction,
an insulation sheet is disposed between the first and second bus bars, and
the insulating medium is formed by extending a part of the insulation sheet.

13. A power semiconductor device, comprising:
a plurality of semiconductor modules; and
a first bus bar and a second bus bar electrically connected to a first main electrode terminal and a second main electrode terminal, respectively, of each of the semiconductor modules,
wherein the semiconductor modules are arrayed without any overlap in a first direction (Z direction) that is a thickness direction,
the first bus bar includes a first bus bar terminal connected to the first main electrode terminal,
the second bus bar includes a second bus bar terminal connected to the second main electrode terminal,
the first and second main electrode terminals are disposed side by side with a space in a second direction (X direction) that is an alignment direction of the semiconductor modules,
the first main electrode terminal protrudes from one side surface of the semiconductor modules,
the second main electrode terminal is covered with a molding resin except a tip of the second main electrode terminal, the molding resin being included in the semiconductor modules,
the first bus bar terminal is formed into a length to cover a protruding portion of the first main electrode terminal and to be connected to the first main electrode terminal, and
the second bus bar terminal is formed into a length to cover the tip of the second main electrode terminal and to be connected to the second main electrode terminal.
